(19) United States
(12) Patent Application Publication
(10) Pub. No.: US 2007/0001316 A1
(43) Pub. Date: Jan. 4, 2007

(54) Semiconductor device with improved signal transmission characteristics

(75) Inventor: Jung-hwan Choi, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/169,393

(22) Filed: Jun. 29, 2005

(30) Foreign Application Priority Data
Jul. 1, 2004 (KR) 04-51005

(51) Int. Cl. H01L 23/48; H01L 23/52

(52) U.S. Cl. 257/779; 257/784; 257/E23.02; 257/E23.021

(57) ABSTRACT

Provided is a semiconductor device with improved signal transmission characteristics. The semiconductor device includes a substrate and a semiconductor chip. The substrate includes connection pads mounted in a central area of a top surface of the substrate, balls attached to a bottom surface of the substrate, and an area on the bottom of the substrate directly below the connection pads which is depopulated of balls. The semiconductor chip Whose bottom surface is mounted on one of the two sections has an edge-pad structure in which chip pads are disposed on a portion of a top surface so as to be adjacent to the connection pads. The connection pads are connected to the corresponding chip pads by bonding wires. The semiconductor chip is less than half the size of the substrate. The chip pads are disposed in the same direction as the connection pads. The connection pads are aligned in one or more rows in a central area of the substrate. The chip pads are aligned on the top surface of the semiconductor chip in one or more rows. The top surface of the substrate is divided by the connection pads into two sections, and the semiconductor chip is mounted on one of the two sections. The semiconductor device has a package structure in which center balls are depopulated and which maintains a consistent length of the bonding wires even when the size of the semiconductor chip is reduced, thereby preventing degradation of signal transmission characteristics and increasing the integration density of the semiconductor chip.

### BACKGROUND OF THE INVENTION

This application claims the priority of Korean Patent Application No. 2004-51005, filed on Jul. 1, 2004, in the Korean Intellectual Property Office, the contents of which are incorporated herein in their entirety by reference.

1. Field of the Invention

The present invention relates to a semiconductor device, and more particularly, to a semiconductor device having a package structure that improves signal transmission characteristics.

2. Description of the Related Art

An advantage of a ball grid array (BGA) package is that it allows a chip scale package. The chip scale package is a technology that reduces package size so that it is close to the size of a semiconductor chip.

FIG. 1A illustrates a conventional semiconductor device 100 having a BGA package structure. Referring to FIG. 1A, the semiconductor device 100 includes a semiconductor chip CP and a substrate SUBT. The semiconductor chip CP includes a circuit pattern (not shown) and chip pads CPDs. Connection pads PDs connected to the chip pads CPDs by bonding wires BWR are formed on a top surface of the substrate SUBT, and balls SBs are formed on a bottom surface of the substrate SUBT.

The semiconductor device 100 of FIG. 1A is structured such that the chip pads CPDs and the balls SBs face in opposite directions. This structure is called a face-up structure since the semiconductor chip CP faces up. Both of the semiconductor chip CP and the substrate SUBT have an edge-pad structure in which the chip pads CPDs and the connection pads PDs are arranged around the edges.

FIG. 1B illustrates another conventional semiconductor device 110 having the BGA package structure. The semiconductor device 110 includes connection pads PDs and chip pads CPDs arranged along some of the four sides of a substrate SUBT and a semiconductor chip CP. However, in the semiconductor device 110, all the connection pads PDs and the chip pads CPDs are placed, respectively, on edges of the substrate SUBT and the semiconductor chip CP.

FIG. 2 is a side view of the semiconductor device 100 of FIG. 1A. Specifically, FIG. 2 is a side view of the semiconductor device 100 taken along line A-A′ of FIG. 1A. The semiconductor chip CP is mounted on the substrate SUBT, and the connection pads PDs on the substrate SUBT are connected to the chip pads CPDs on the semiconductor chip CP by the bonding wires BWR. The balls SBs are connected to a bottom surface of the substrate SUBT.

FIG. 3 illustrates another conventional semiconductor device 200 having the BGA package structure. FIG. 4 is a side view of the semiconductor device 200 of FIG. 3.

The semiconductor 200 of FIGS. 3 and 4 is structured such that center balls SBs of a substrate SUBT are depopulated in order to use a center pad structure of a semiconductor chip CP. The semiconductor device 200 has a section removed in the center of the substrate SUBT where the center balls SBs are depopulated, and the semiconductor chip CP is mounted on the substrate SUBT to face the center balls SBs. This is called a face-down structure.

Since chip pads CPDs face the substrate SUBT, the chip pads CPDs and connection pads PDs cannot be seen in a top view of the semiconductor device 200. Therefore, bonding wires BWR1 connecting the chip pads CPDs and the connection pads PDs are expressed as a dotted line. The connection pads PDs and the balls SBs are connected by a via or a metal line BWR2.

The semiconductor device 200 with such structure has superior semiconductor chip CP and substrate SUBT characteristics since its center pad structure exhibits relatively superior loading to the edge-pad structure, and the substrate SUBT realizes low parasitic loading.

If the size of the semiconductor chip CP of the semiconductor device 200 of FIG. 3 is reduced, the bonding wires BWR1 connecting the chip pads CPDs of the semiconductor chip CP and the connection pads PDs of the substrate SUBT are lengthened.

The long bonding wires BWR1 have inferior signal transmission characteristics. In addition, a smaller semiconductor chip CP may cause a fan-out problem.

### SUMMARY OF THE INVENTION

The present invention provides a semiconductor device having a package structure in which center balls are depopulated, and which maintains a consistent length of bonding wires even when a size of a semiconductor chip is reduced, thereby preventing degradation of signal transmission characteristics and increasing integration density of the semiconductor chip.

According to an aspect of the present invention, there is provided a semiconductor device including a substrate and a semiconductor chip. The substrate includes connection pads mounted in a central area of a top surface of the substrate, balls attached to a bottom surface of the substrate, and an area on the bottom of the substrate directly below the connection pads which is depopulated of balls. A bottom surface of the semiconductor chip is mounted on the top surface of the substrate. The semiconductor chip has an edge-pad structure in which chip pads are disposed on a portion of a top surface of the semiconductor chip adjacent to the connection pads. The connection pads are connected to the corresponding chip pads by bonding wires.

In one embodiment, the semiconductor chip is less than half the size of the substrate.

The chip pads can be disposed in the same direction as the connection pads.

The connection pads can be aligned in one or more rows in a central area of the substrate. The chip pads can be aligned on the top surface of the semiconductor chip in one or more rows.

The top surface of the substrate can be divided by the connection pads into two sections, and the semiconductor chip can be mounted on one of the two sections. An additional semiconductor chip can be mounted on the other section of the substrate, and the additional semiconductor chip may not be connected to the connection pads.

According to another aspect of the present invention, there is provided a semiconductor device including a substrate, a first semiconductor chip, and a second semiconductor chip. The substrate includes connection pads mounted in a central area of a top surface of the substrate, balls attached to a bottom surface of the substrate, and an area on the bottom of the substrate directly below the connection pads which is depopulated of balls, and having the top surface divided by the connection pads into two sections. The first semiconductor chip whose bottom surface is mounted on one of the two sections has an edge-pad structure in which chip pads are disposed on a portion of a top surface adjacent to the connection pads. The second semiconductor chip whose bottom surface is mounted on the other section has the edge-pad structure in which chip pads are disposed on a portion of a top surface adjacent to the connection pads. The connection pads are connected to the corresponding chip pads of the first and second semiconductor chips by bonding wires.

In one embodiment, the first and second semiconductor chips are less than half the size of the substrate.

The chip pads can be disposed in the same direction as the connection pads. The connection pads can be aligned in one or more rows in a central area of the substrate.

The chip pads can be aligned on the top surface of the semiconductor chip in one or more rows. The first and second semiconductor chips be either identical or different.

According to another aspect of the present invention, there is provided a semiconductor device including a substrate and a semiconductor chip. The substrate whose top surface is divided into two sections by connection pads mounted thereon includes balls attached to a bottom surface of the substrate exempting a central portion of the bottom surface directly below the connection pads. The semiconductor chip whose bottom surface is mounted on one of the two sections includes chip pads mounted on a top surface connected to the connection pads by bonding wires. The semiconductor chip is less than half the size of the substrate.

In one embodiment, the chip pads have an edge-pad structure in which the chip pads aredisposed on a portion of the top surface of the semiconductor chip adjacent to the connection pads, and the chip pads are disposed in the same direction as the connection pads. The connection pads can be aligned in one or more rows in a central area of the substrate.

The chip pads can be aligned on the top surface of the semiconductor chip in one or more rows. An additional semiconductor chip is mounted in the other section on the top surface of the substrate, and the additional semiconductor chip is not connected to the connection pads.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1A illustrates a conventional semiconductor device having a ball grid array (BGA) package structure.

FIG. 1B illustrates another conventional semiconductor device having the BGA package structure.

FIG. 2 is a side view of the semiconductor device of FIG. 1A.

FIG. 3 illustrates another conventional semiconductor device having the BGA package structure.

FIG. 4 is a side view of the semiconductor device of FIG. 3.

FIG. 5A illustrates a semiconductor device according to an embodiment of the present invention.

FIG. 5B is a side view of the semiconductor device of FIG. 5A.

FIG. 6A illustrates a semiconductor device according to another embodiment of the present invention.

FIG. 6B is a side view of the semiconductor device of FIG. 6A.

FIG. 7A illustrates a semiconductor device according to another embodiment of the present invention.

FIG. 7B is a side view of the semiconductor device of FIG. 7A.

FIG. 8A illustrates a semiconductor device according to another embodiment of the present invention.

FIG. 8B is a side view of the semiconductor device of FIG. 8A.

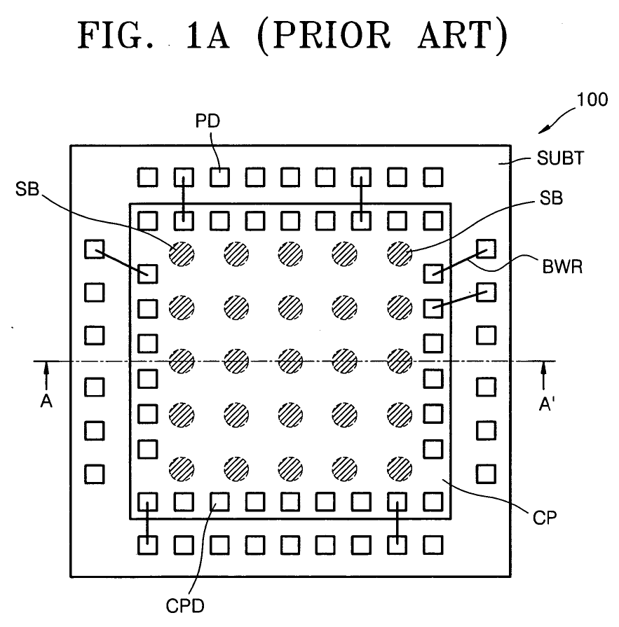

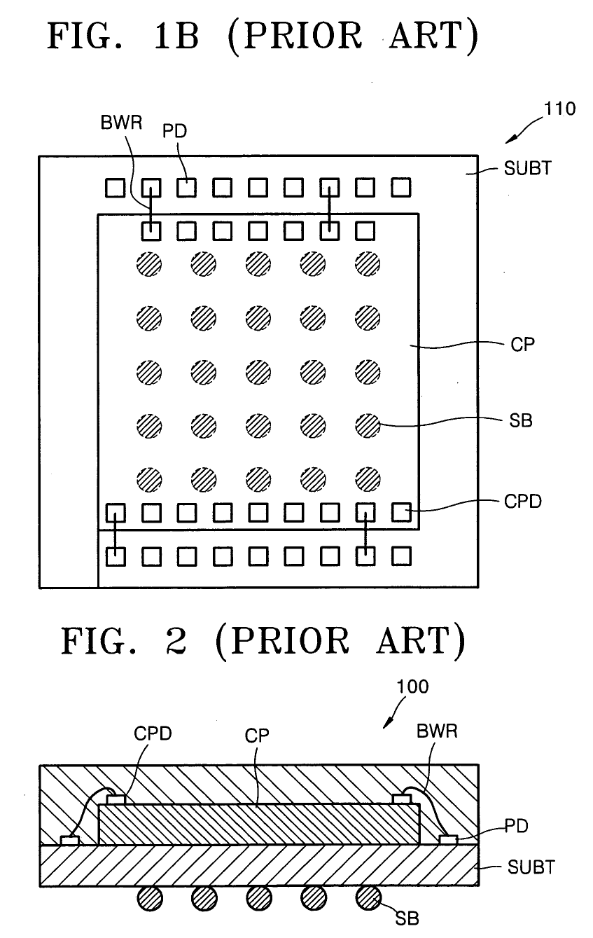

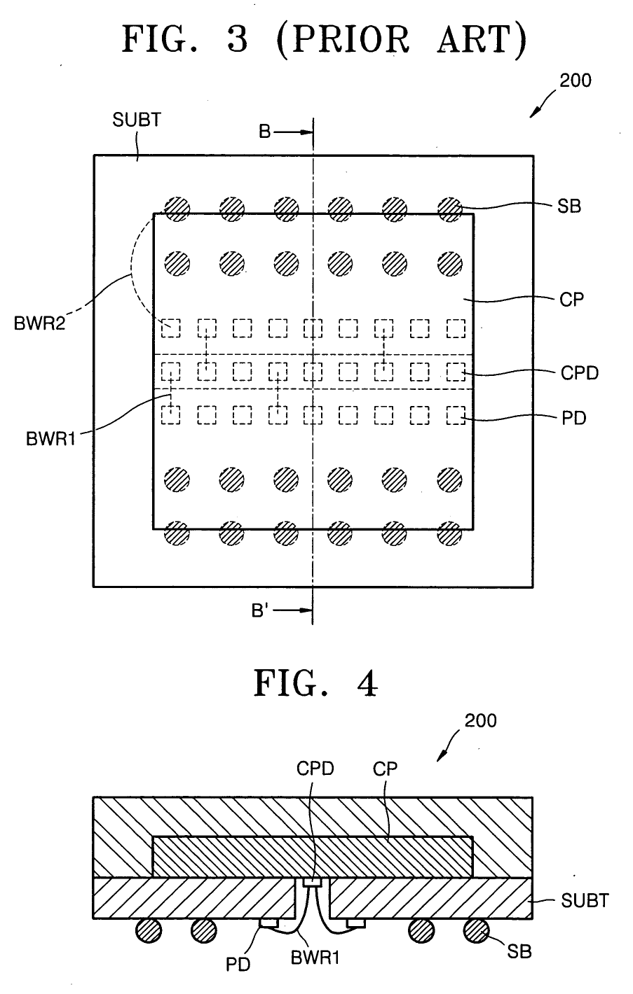

### DETAILED DESCRIPTION OF THE INVENTION

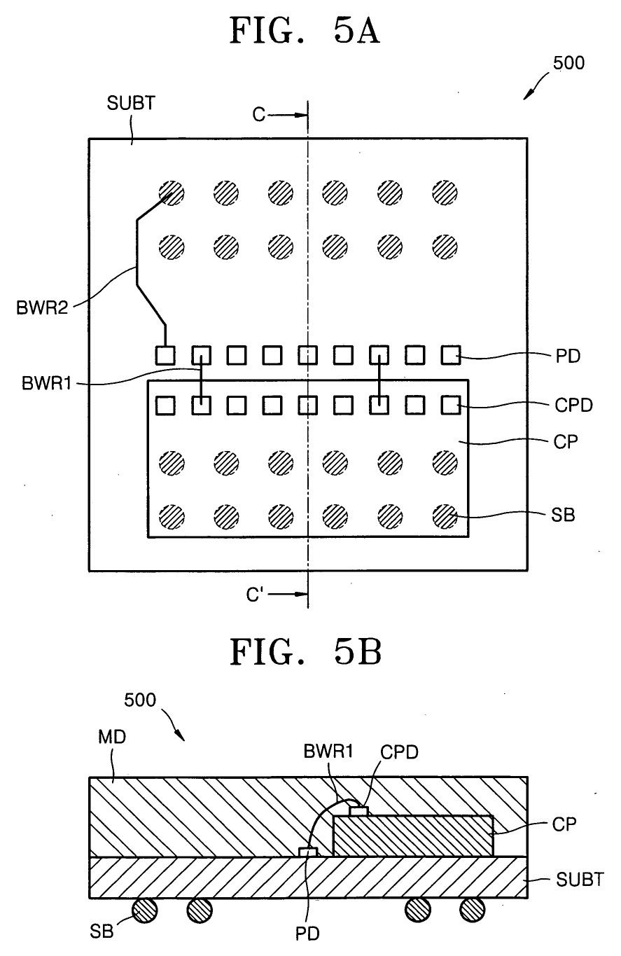

FIG. 5A illustrates a semiconductor device 500 according to an embodiment of the present invention. FIG. 5B is a side view of the semiconductor device 500 of FIG. 5A.

Referring to FIG. 5A, the semiconductor device 500 has a face-up structure. That is, chip pads CPDs and a substrate SUBT face in opposite directions. Balls SBs are formed on a bottom surface of the substrate SUBT.

Connection pads PDs are aligned in a row in a central area of a top surface of the substrate SUBT corresponding to an area where the balls SBs of the bottom. surface of the substrate SUBT have been depopulated. The connection pads PDs are aligned in a row in FIG. 5A, but they may be aligned in two or more rows.

The substrate SUBT is divided into two sections by the connection pads PDs, and a semiconductor chip CP, which is less than half the size of the substrate SUBT, is mounted in one section. The chip pads CPDs are adjacent to the connection pads PDs of the substrate SUBT. This constitutes an edge-pad structure.

Bonding wires BWR1, which can be shortened, connect the chip pads CPbs on the semiconductor chip CP to the connection pads PDs. In addition, the length of the bonding wires BWR1 remains consistent.

Here, the connection pads PDs on the substrate SUBT are connected to the balls SBs by a via or a metal line BWR2. The via may be freely disposed around the connection pads PDs or the balls SBs. This metal line BWR2 is not illustrated in FIG. 5B.

The chip pads CPDs are aligned in a row on a top surface of the semiconductor chip CP in FIG. 5A, but may be aligned in two or more rows. After the connection pads PDs and the chip pads CPDs have been connected, the bonding wires BWR1 and the semiconductor chip CP are protected by a molding.

FIG. 5B is a side view of the semiconductor device 500 surrounded by a compound MD produced by a molding process.

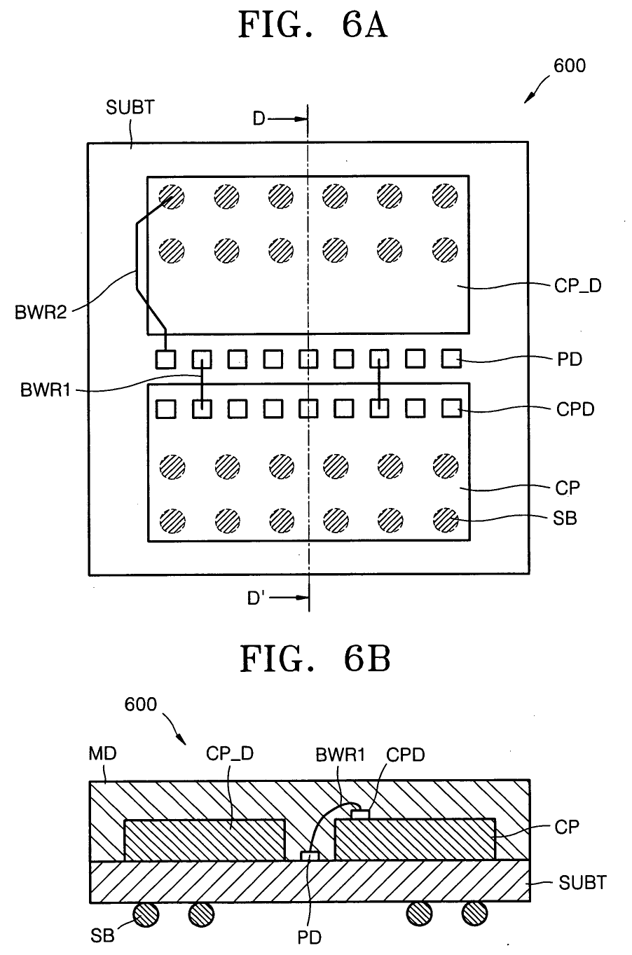

FIG. 6A illustrates a semiconductor device 600 according to another embodiment of the present invention. FIG. 6B is a side view of the semiconductor device 600 of FIG. 6A.

In addition to the elements of the semiconductor device 500 of FIG. 5A, the semiconductor device 600 includes another semiconductor chip CP_D. In the illustrated exemplary embodiment, the semiconductor chip CP_D is not connected to connection pads PDs.

In the semiconductor device 500 of FIG. 5A, the semiconductor chip CP is mounted on only one section of the substrate SUBT. Therefore, the other section of the substrate SUBT where the semiconductor chip CP is not mounted is stressed more by a compound MD than the section of the substrate SUBT where the semiconductor chip is mounted.

Hence, there is a possibility that the semiconductor device 500 will deform or its physical characteristics will deteriorate or degrade after the molding process. To eliminate this possibility, the additional semiconductor chip CP_D is mounted on the other section of the substrate SUBT.

The semiconductor chip CP_D is not a normal semiconductor chip but a dummy semiconductor chip for preventing the deformation of the semiconductor device 600. Accordingly, the semiconductor chip CP_D is not connected to the connection pads PDs on the substrate SUBT.

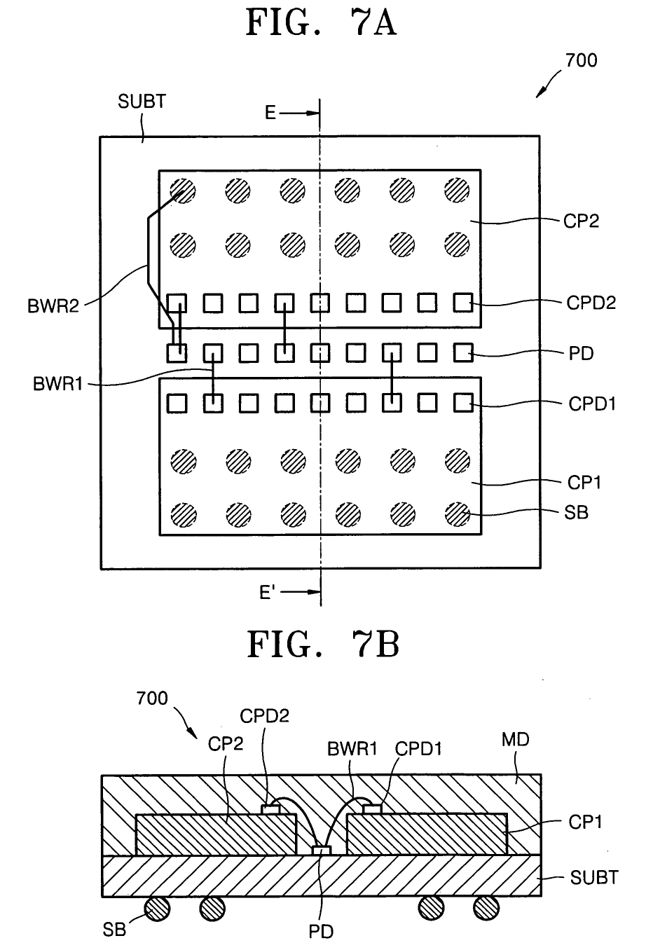

FIG. 7A illustrates a semiconductor device 700 according to another embodiment of the present invention. FIG. 7B is a side view of the semiconductor device 700 of FIG. 7A.

Referring to FIG. 7A, the semiconductor device 700 includes a substrate SUBT, a first semiconductor chip CP1, and a second semiconductor chip CP2. Connection pads PDs are disposed in the central area of a top surface of the substrate, and balls SBs are attached to a bottom surface of the substrate SUBT. The area on the bottom surface of the substrate SUBT below the connection pads PDs does not contain any balls SBs. The top surface of the substrate SUBT is divided into two sections by the connection pads PDs.

The first semiconductor chip CP1 is mounted on one section of the substrate SUBT. In an edge structure, chip pads CPD1s are mounted on a portion of a top surface of the first semiconductor chip CP1 so as to be adjacent to the connection pads PDs. The chip pads CPD1s are disposed in a line that is parallel to the line the connection pads PDs are disposed along.

In an edge structure, chip pads CPD2s are mounted on a portion of a top surface of the second semiconductor chip CP2 so as to be adjacent to the connection pads PDs. The chip pads CPD2s are disposed in a line that is parallel to the line the connection pads PDs are disposed along.

The connection pads PDs are connected to the corresponding chip pads CPD1s and CPD2s on the first and the second semiconductor chips CP1 and CP2 by bonding wires BWR1. The first and the second semiconductor chips CP1 and CP2 are each less than half the size of the substrate SUBT.

Unlike the semiconductor devices 500 and 600 of FIGS. 5 and 6, the semiconductor device 700 of FIG. 7A includes the two functional semiconductor chips CP1 and CP2.

In the semiconductor device 700 of FIG. 7A, the bonding wires BWR1 connecting the chip pads CPD1 s and CPD2s of the semiconductor chips CP1 and CP2 have an equal and short length, thereby improving signal transmission characteristics. The connection pads PDs and the balls SBs are connected by a via or a metal line BWR2. The metal line BWR2 illustrated in FIG. 7A is not illustrated in FIG. 7B.

There is no limit to how the chip pads CPD1s and CPDs 2 of the first and second semiconductor chips CP1 and CP2 are connected to one another.

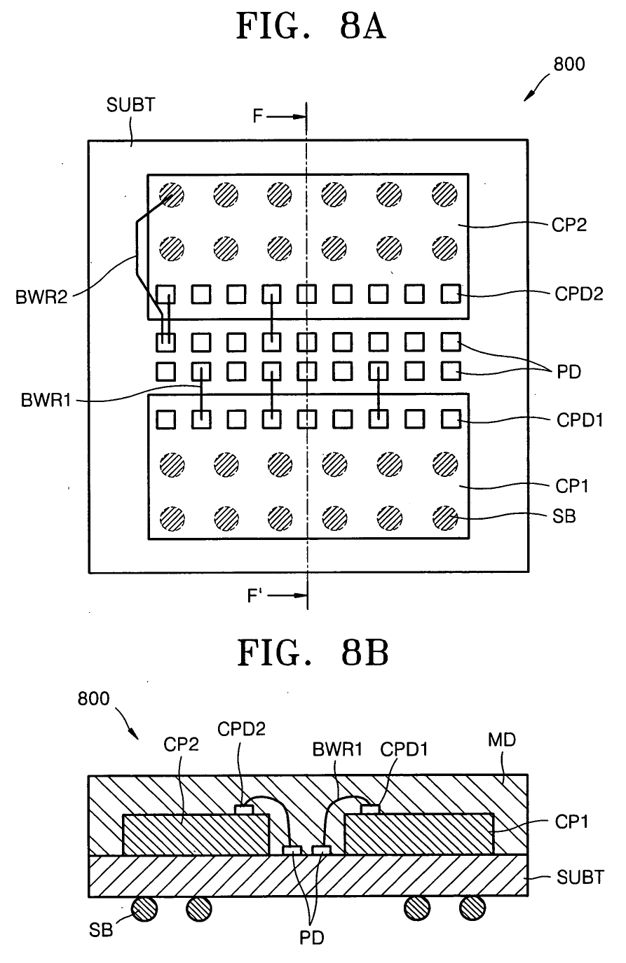

FIG. 8A illustrates a semiconductor device 800 according to another embodiment of the present invention. FIG. 8B is a side view of the semiconductor device 800 of FIG. 8A.

Unlike the semiconductor device 700 of FIG. 7A, the semiconductor device 800 of FIG. 8A includes two rows of connection pads PDs. The structure of the semiconductor device 800 of FIG. 8A is identical to that of the semiconductor device 700 of FIG. 7A except for the structure of the connection pads PDs.

The connection pads PDs are aligned in two rows on the substrate SUBT but they may be aligned in more rows. In addition, chip pads CPD1s and CPD2s can be aligned in two or more than two rows.

Even though the connection pads PDs are aligned in two rows, there is no limit to how the chip pads CPD1s and CPD2s of the first and the second semiconductor chips CP1 and CP2 are connected to the connection pads PDs.

As described above, a semiconductor device according to the present invention has a package structure in which center balls are depopulated and maintains a consistent length of bonding wires even when the size of a semiconductor chip is reduced, thereby preventing deterioration or degradation of signal transmission characteristics and increasing the integration density of the semiconductor chip.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor device comprising:
a substrate comprising connection pads mounted in a central area of a top surface of the substrate, balls attached to a bottom surface of the substrate, and an area on the bottom of the substrate directly below the connection pads which is depopulated of balls; and
a semiconductor chip whose bottom surface is mounted on the top surface of the substrate and having an edge-pad structure in which chip pads are disposed on a portion of a top surface of the semiconductor chip adjacent to the connection pads,
wherein the connection pads are connected to the corresponding chip pads by bonding wires.

2. The semiconductor device of claim 1, wherein the semiconductor chip is less than half the size of the substrate.

3. The semiconductor device of claim 1, wherein the chip pads are disposed in the same direction as the connection pads.

4. The semiconductor device of claim 1, wherein the connection pads are aligned in one or more rows in a central area of the substrate.

5. The semiconductor device of claim 1, wherein the chip pads are aligned on the top surface of the semiconductor chip in one or more rows.

6. The semiconductor device of claim 1, wherein the top surface of the substrate is divided by the connection pads into two sections, and the semiconductor chip is mounted on one of the two sections.

7. The semiconductor device of claim 6, wherein an additional semiconductor chip is mounted on the other section of the substrate, and the additional semiconductor chip is not connected to the connection pads.

8. A semiconductor device comprising:
a substrate comprising connection pads mounted in a central area of a top surface of the substrate, balls attached to a bottom surface of the substrate, and an area on the bottom of the substrate directly below the connection pads which is depopulated of balls, and having the top surface divided by the connection pads into two sections; and
a first semiconductor chip whose bottom surface is mounted on one of the two sections and having an edge-pad structure in which chip pads are disposed on a portion of a top surface adjacent to the connection pads; and
a second semiconductor chip whose bottom surface is mounted on the other section and having the edge-pad structure in which chip pads are disposed on a portion of a top surface adjacent to the connection pads,
wherein the connection pads are connected to the corresponding chip pads of the first and second semiconductor chips by bonding wires.

9. The semiconductor device of claim 8, wherein the first and second semiconductor chips are less than half the size of the substrate.

10. The semiconductor device of claim 8, wherein the chip pads are disposed in the same direction as the connection pads.

11. The semiconductor device of claim 8, wherein the connection pads are aligned in one or more rows in a central area of the substrate.

12. The semiconductor device of claim 8, wherein the chip pads are aligned on the top surface of the semiconductor chip in one or more rows.

13. The semiconductor device of claim 8, wherein the first and second semiconductor chips are identical.

14. The semiconductor device of claim 8, wherein the first and second semiconductor chips are different.

15. A semiconductor device comprising:
a substrate whose top surface is divided into two sections by connection pads mounted thereon, and comprising balls attached to a bottom surface of the substrate exempting a central portion of the bottom surface directly below the connection pads; and
a semiconductor chip whose bottom surface is mounted on one of the two sections, and which comprises chip pads mounted on a top surface connected to the connection pads by bonding wires,
wherein the semiconductor chip is less than half the size of the substrate.

16. The semiconductor device of claim 15, wherein the chip pads have an edge-pad structure in which the chip pads are disposed on a portion of the top surface of the semiconductor chip adjacent to the connection pads, and the chip pads are disposed in the same direction as the connection pads.

17. The semiconductor device of claim 15, wherein the connection pads are aligned in one or more rows in a central area of the substrate.

18. The semiconductor device of claim 15, wherein the chip pads are aligned on the top surface of the semiconductor chip in one or more rows.

19. The semiconductor device of claim 15, wherein an additional semiconductor chip is mounted in the other section on the top surface of the substrate, and the additional semiconductor chip is not connected to the connection pads.
